(19) United States
(12) Patent Application Publication
(10) Pub. No.: US 2008/0061406 A1
(43) Pub. Date: Mar. 13, 2008

(54) SEMICONDUCTOR PACKAGE HAVING ELECTROMAGNETIC SHIELDING PART

(76) Inventor: Cheol Ho JOH, Seoul (KR)

Correspondence Address: LADAS & PARRY LLP, 224 SOUTH MICHIGAN AVENUE, SUITE 1600, CHICAGO, IL, 60604, US

(21) Appl. No.: 11/760,239

(22) Filed: Jun. 8, 2007

(30) Foreign Application Priority Data
Sep. 12, 2006 (KR) 10-2006-0088231

(51) Int. Cl. H01L 23/552

(52) U.S. Cl. 257/660; 257/E23.114

(57) ABSTRACT

A semiconductor package includes a semiconductor chip; and an encapsulant for covering the semiconductor chip, such that the encapsulant includes a molding part for covering the semiconductor chip to protect the semiconductor chip from the external environment; and an electromagnetic shielding part for covering an outer surface of the molding part and containing therein electrically conductive particles for shielding an electromagnetic wave radiated from the semiconductor chip to the outside and an electromagnetic wave incident from the outside to the semiconductor chip.

### CROSS-REFERENCE TO RELATED APPLICATIONS

The present application claims priority to Korean patent application number 10-2006-0088231 filed on Sep. 12, 2006, which is incorporated herein by reference in its entirety.

### BACKGROUND OF THE INVENTION

The present invention relates to a semiconductor package, and more particularly to a semiconductor package for shielding an electromagnetic wave radiated from a semiconductor package or incident to the semiconductor package.

The processes for fabricating a semiconductor device include: a semiconductor chip fabrication process for fabricating semiconductor chips on a silicon wafer of high purity silicon, a die sorting process for testing the fabricated semiconductor chips and sorting out the good semiconductor chips, and a packaging process for packaging the sorted-out good semiconductor chips.

The packaging process for packaging the sorted-out good semiconductor chips includes, in general: a die attach process for attaching a semiconductor chip to an upper surface of a base substrate coated with adhesive, a wire bonding process for electrically connecting the semiconductor chip and the base substrate by connecting the bonding pads of the semiconductor chip and the electrode terminals on the upper peripheral surface of the base substrate with conductive wires, and a molding process for covering the upper surface of the base substrate with a molding resin so as to protect the semiconductor chip and the wires from the external environment.

When a semiconductor package fabricated through the processes discussed above is mounted on an electronic circuit board with other electronic components, electromagnetic interference (EMI) caused by the electromagnetic waves emanating from the semiconductor package in operation may cause problems to other electronic components. The EMI may cause electromagnetic noise and malfunctioning of the electronic circuit, thereby deteriorating the product reliability.

Particularly, problems due to EMI are becoming more serious as the semiconductor packages are made for higher speed and higher capacity. For example, shielding to prevent EMI can be difficult in a notebook computer due to spatial limitations, such that the EMI generated from an ineffectively shielded semiconductor chip in the notebook computer could cause the system to fail. Therefore, there is an urgent need to effectively minimize the EMI phenomenon when realizing an electronic device.

### BRIEF SUMMARY OF THE INVENTION

Embodiments of the present invention are directed to a semiconductor package capable of shielding an electromagnetic wave generated from the semiconductor package and radiated to the outside.

Further, embodiments of the present invention are directed to a semiconductor package for shielding an electromagnetic wave generated from the semiconductor package and thus preventing an EMI and a resultant generation of a defect.

Furthermore, embodiments of the present invention are directed to a semiconductor package for preventing the EMI and the resultant generation of a defect thereby capable of improving a reliability of an electronic device.

In one embodiment, a semiconductor package may include a semiconductor chip; and an encapsulant for covering the semiconductor chip, wherein the encapsulant includes a molding part for covering the semiconductor chip to protect the semiconductor chip from the external environment; and an electromagnetic shielding part for covering an outer surface of the molding part and containing therein electrically conductive particles for shielding an electromagnetic wave radiated from the semiconductor chip to the outside and an electromagnetic wave incident from the outside to the semiconductor chip.

The molding part is formed of an epoxy molding compound.

The electromagnetic shielding part is formed of one of an epoxy molding compound, a film and paints which are contains the electrically conductive particles.

The electrically conductive particle is any one selected from group consisting of carbon, metal, and ferrite.

The electrically conductive particle is contained in an amount of 1 to 50 wt %.

In another embodiment, a semiconductor package may include a base substrate provided with electrode terminals; a semiconductor chip attached onto an upper surface of the base substrate and arranged with a plurality of bonding pads over an upper surface thereof; conductive wires for connecting electrically the bonding pad of the semiconductor chip and the electrode terminal of the base substrate; a molding part for covering the upper surface of the base substrate including the semiconductor chip and the conductive wires; an electromagnetic shielding part for covering an outer surface of the molding part and containing therein electrically conductive particles for shielding an electromagnetic wave radiated from the semiconductor chip to the outside and an electromagnetic wave incident from the outside to the semiconductor chip; and an external connection terminal attached to a lower surface of the base substrate.

The molding part is formed of an epoxy molding compound.

The electromagnetic shielding part is formed of one of an epoxy molding compound, a film and paints which are contains the electrically conductive particles.

The electrically conductive particle is any one selected from group consisting of carbon, metal, and ferrite.

The electrically conductive particle is contained in an amount of 1 to 50 wt %.

### BRIEF DESCRIPTION OF THE DRAWINGS

FIGS. 1 to 4 are cross-sectional views showing a semiconductor package having an electromagnetic shielding part in accordance with an embodiment of the present invention and a method for fabricating the same.

### DESCRIPTION OF SPECIFIC EMBODIMENTS

A preferred embodiment of the present invention is directed to a semiconductor package, in which an electromagnetic shielding part is further formed over an outer surface of a molding part formed so as to protect the semiconductor package from the external environment and, through the electromagnetic shielding part, an electromagnetic wave radiated from a semiconductor chip to the outside and an electromagnetic wave incident from the outside to the semiconductor chip are shielded. In other words, in the present invention, after forming the molding part by molding firstly the semiconductor chip with a conventional epoxy molding compound, the electromagnetic shielding part covering the outer surface of the molding part is formed of a material containing a large amount of electrically conductive particles consisting of carbon, metal, and ferrite etc thereby forming an encapsulant in a double structure.

In this case, an electromagnetic wave radiated from a semiconductor chip to the outside and an electromagnetic wave incident from the outside to the semiconductor chip can be completely shielded. This uses a principle that when an electromagnetic wave collides with a particle having an electric conductivity, it is converted to thermal energy or extinguished due to diffuse reflection. Therefore, in an embodiment of the present invention, it can be prevented that an electromagnetic wave radiated from a semiconductor chip has a bad influence on adjacent electric parts and thus causes an electromagnetic noise or a malfunction.

Meanwhile, in order to improve the EMI phenomenon in a package level, there has been introduced a method for putting electrically conductive particles into a molding part material, which is conventionally formed so as to protect a semiconductor chip and a conductive wire from the external environment, for example an epoxy molding compound resin. However, if the electrically conductive particles are contained much in the molding resin covering directly the semiconductor chip, an electric shortage occurs between the conductive wires due to the electrically conductive particles thereby causing a defect in a product. Therefore, in order to prevent the occurrence of the electric shortage between the conductive wires due to the electrically conductive particles, an amount of the electrically conductive particles contained in the molding resin should be limited to lower than 1 wt % of an amount of the molding resin.

However, since the effect of shielding an electromagnetic wave is also limited in the case that the amount of the electrically conductive particles contained in the molding resin is limited to lower than 1 wt %, large amount of the electromagnetic wave which is not distinguished by the electrically conductive particles may be still radiated to the outside of the semiconductor package or the electromagnetic wave generated from other adjacent part may be incident to an inside of the semiconductor package and as the result, malfunction of the electronic device mounted with the semiconductor package may be caused.

In addition, though the amount of the electrically conductive particles is extremely limited, a risk of an electrical shortage between the conductive wires is still remained due to the electrically conductive particles.

To the contrary, in an embodiment of the present invention, because after the molding part is formed by firstly molding the semiconductor chip and the conductive wires with the molding resin containing no electrically conductive particle, the outer surface of the molding part is secondly molded with a material containing the electrically conductive particle in a large amount of more than 1 wt %, preferably 1 to 50 wt %, it is free from the problem of the shortage of the conductive wire and has a secure electromagnetic shielding effect, thereby capable of preventing effectively an occurrence of defect due to the electromagnetic wave.

More specifically, a semiconductor package having an electromagnetic shielding part in accordance with an embodiment of the present invention and a method for fabricating the same will be described hereinafter with reference to the attached drawings.

FIG. 4 shows a cross-sectional view of a semiconductor package made in accordance with an embodiment of the present invention. A semiconductor chip 120 is attached to the upper surface of a base substrate 110 using an adhesive agent 125 therebetween, and the electrode terminals 112 of the base substrate 110 and the bonding pads 122 of the semiconductor chip 120 are electrically connected by the conductive wires 130. A molding part 140 covers the upper surface of the base substrate 110 including the semiconductor chip 120 and the conductive wires 130, and the outer surface of the molding part 140 is covered with an electromagnetic shielding part 150 containing a large amount of electrically conductive particles. An external connection terminal 160 is attached to a ball land 160 on a lower surface of the base substrate 110.

The base substrate 110 is a printed circuit board formed with a plurality of the electrode terminals 112 arranged over the upper surface thereof, a plurality of the ball lands 114 arranged over the lower surface thereof, and other related circuit wirings (not shown). The electrode terminals 112 are arranged over the upper surface of the base substrate 110 outside the area where the semiconductor chip 120 is to be attached, and the electrode terminals 112 are arranged in the direction along or near the bonding pads 122 of the semiconductor chip 120. The electrode terminals 112 and the ball lands 114 are electrically connected to each other by circuit wiring (not shown in FIG. 4) in pairs or other predetermined circuit arrangement.

The semiconductor chip 120, for example, could be an edge pad type chip in which the bonding pads 122 are arranged in the periphery of the upper surface, and the semiconductor chip 120 could be attached to the base substrate 110 in a face-up manner.

The external connection terminal 160 is attached to the ball land 114 of the base substrate 110. Preferably, the external connection terminal 160 is a solder ball having a desired diameter.

It is also possible to substitute the printed circuit board base substrate 110 with a lead frame having a die pad attached to a semiconductor chip and leads used as external connection terminals.

The conductive wire 130 electrically connects the bonding pad 122 of the semiconductor chip 120 and the electrode terminal 112 of the base substrate 110. Therefore, one end of the conductive wire 130 is connected to the bonding pad 122 of the semiconductor chip 120 and the other end is connected to the electrode terminal 112 of the base substrate 110.

The molding part 140 is made of molding resin and covers the upper surface of the base substrate 110 including the semiconductor chip 120 and the conductive wire 130 to protect them from the external environment. The molding resin is an epoxy molding compound including filler, which forms a skeleton of the molding part 140 and does not absorb moisture at a high temperature and thus increases durability and strength, and a reaction material. Preferably, the filler is a silica particle.

The electromagnetic shielding part 150 is formed in the outer surface of the molding part 140 to block the electromagnetic wave radiating outwardly from the semiconductor package 100 and to shield the semiconductor package 100 from being affected by external EMI generated from other electronic devices.

When a plurality of semiconductor chips (such as 120) are fabricated on a common base substrate, the entire upper surface of the base substrate having the plurality of the semiconductor chips attached is molded and then sawed into separate pieces for mass production. In this case, the electromagnetic shielding part (such as 150) is formed over only the upper surface with the molding part (such as 140) when the semiconductor packages are separated into individual pieces by sawing the base substrate 110. FIG. 4 shows a case of fabricating a semiconductor package as an individual unit, and in this case, the electromagnetic shielding part 150 is formed over the entire outer surface including the top and side surfaces of the molding part 140.

For example, the electromagnetic shielding part 150 is formed with a molding resin containing the electrically conductive particle in a large amount of at least 1% by weight, for example, 1 to 50% by weight. Preferably, the molding resin is an epoxy molding compound including a filler that forms a skeleton of the electromagnetic shielding part 150 and does not absorb moisture at a high temperature and thus increases durability and strength of the electromagnetic shielding part 150, a reaction material, and the electrically conductive particles that convert the electromagnetic wave to thermal energy or reflect to extinguish the electromagnetic wave.

For another example, the electromagnetic shielding part 150 is made of a reaction material that cures an adhesive agent by internal heat of the adhesive agent and a film containing electrically conductive particles in a large amount of at least 1% by weight (for example, 1 to 50% by weight) that convert the electromagnetic wave to thermal energy or cause reflection to extinguish the electromagnetic wave.

For yet another example, the electromagnetic shielding part 150 is made of coatable or paintable material containing electrically conductive particles in a large amount of at least 1% by weight, for example, 1 to 50% by weight.

As described above, according to various embodiments of the present invention, the electromagnetic shielding part containing a large amount of the electrically conductive particles is formed so as to cover the outer surface of the molding part and thus the encapsulant is formed in a double structure. In this case, because the electrically conductive particles for extinguishing an electromagnetic wave and the conductive wires are not in direct contact with each other, it is possible to prevent a shortage between the conductive wires due to the electrically conductive particle.

In addition, according to various embodiments of the present invention, because the electromagnetic shielding part is formed over the outer surface of the molding part, the electromagnetic shielding part can contain the electrically conductive particles for extinguishing an electromagnetic wave in a large amount and thus can protect almost perfectly an electromagnetic wave.

Hereinafter, a method for fabricating a semiconductor package having an electromagnetic shielding part in accordance with an embodiment of the present invention will be described with reference to the attached drawings.

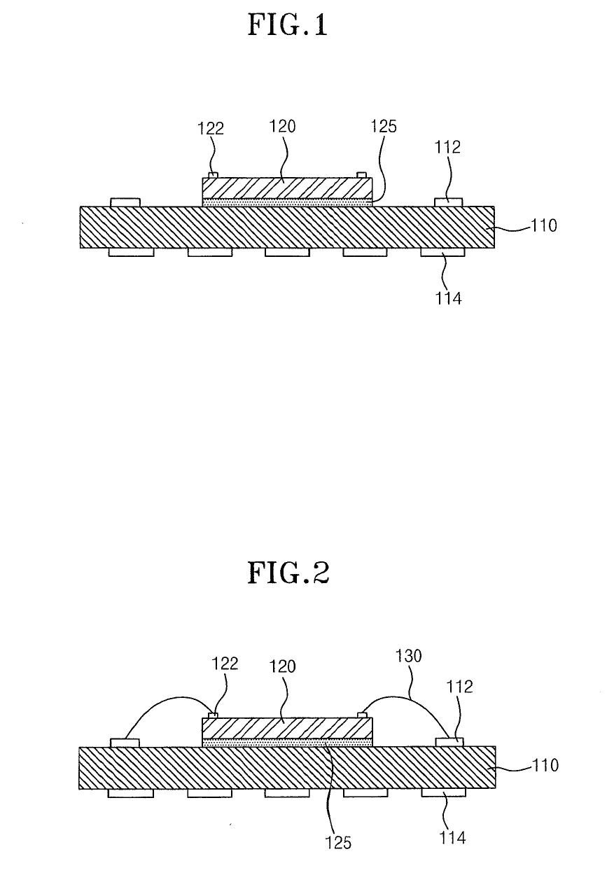

Referring to FIG. 1, after the adhesive agent 125 is applied over the center of the upper surface of the base substrate 110, the semiconductor chip 120 is positioned over the applied adhesive agent 125 according to a die attach process, thereby attaching the semiconductor chip 120 onto the upper surface of the base substrate 110. The semiconductor chip 120 is attached onto the base substrate 110 in a face-up type manner.

Referring to FIG. 2, the bonding pads 122 arranged on the upper peripheral surface of the semiconductor chip 120 and the electrode terminals 112 arranged on the upper surface of the base substrate 110 are respectively connected to each other in pairs or in a predetermined manner via the conductive wire 130 according to a wire bonding process, by which the semiconductor chip 120 and the base substrate 110 are electrically connected.

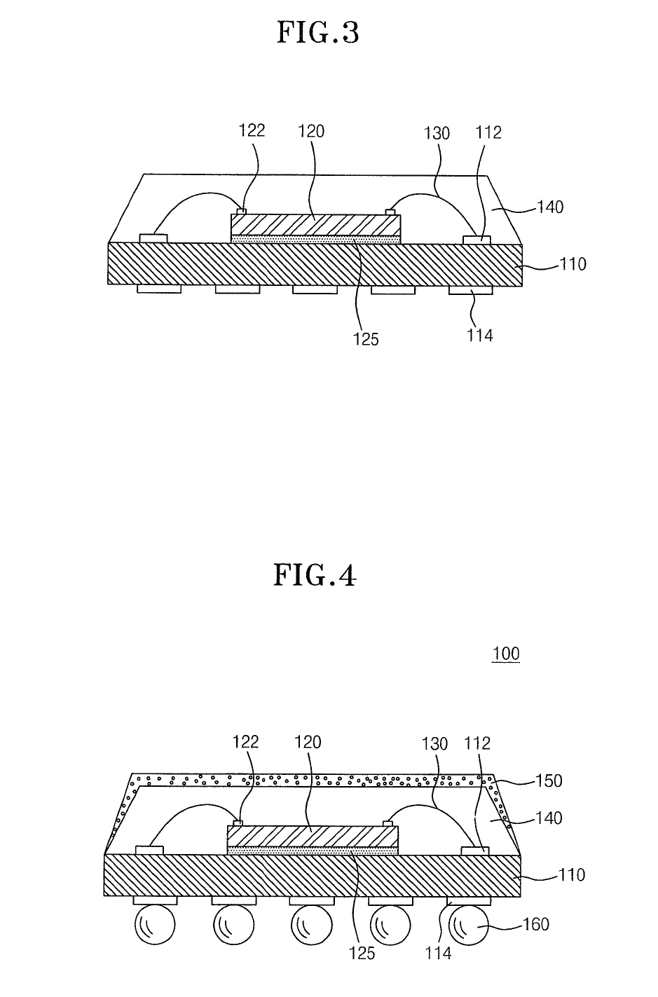

Referring to FIG. 3, the upper surface of the base substrate 110 including the semiconductor chip 120 and the conductive wire 130 is covered with the molding resin according to a molding process, thereby forming the molding part 140 for protecting them from the external environment.

Referring to FIG. 4, the electromagnetic shielding part 150 is formed so as to cover the outer surface of the molding part 140 in the similar manner of forming the molding part, and the electromagnetic shielding part 150 blocks the electromagnetic wave radiating outwardly from the semiconductor package 100 and shields the semiconductor package 100 from being affected by external EMI generated from other electronic devices.

External connection terminals 160 such as solder balls are attached to the ball lands 114 formed on the lower surface of the base substrate 110, thereby fabricating the semiconductor package 100 in accordance with an embodiment of the present invention.

In case of forming the electromagnetic shielding part 150 with molding resin, the base substrate 110 formed with the molding part 140 is positioned over a lower mold die of a molding mold and an upper mold die formed with a cavity covers over the lower mold die. The molding part 140 formed over the base substrate 110 is located inside the cavity.

After that, a heater positioned in the lower mold die is operated to melt the solid state epoxy molding compound containing the large amount of the electrically conductive particles to a liquid state, and the epoxy molding compound is injected into the cavity in which the molding part is positioned, thereby filling the inside of the cavity with the epoxy molding compound. Subsequently, the liquid state epoxy molding compound is cured at a high temperature for a desired duration, thereby forming the electromagnetic shielding part 150 over the outer surface of the molding part 140.

Herein, the epoxy molding compound could be used for forming the molding part 140, and the epoxy molding compound containing electrically conductive particles could be used to form the electromagnetic shielding part 150 by covering the molding part 140. Then, these two types of epoxy molding compounds may be cured simultaneously, by which the semiconductor package 100 fabrication time can be shortened.

When forming the electromagnetic shielding part 150 using film, a film having adhesive quality and containing a large amount of the electrically conductive particles is attached to the outer surface of the molding part 140, and then high temperature heat is applied to the film to cure the film, thereby forming the electromagnetic shielding part 150. The curing of the film and the curing of the molding part 140 can be performed together to shorten the process time.

More specifically, about 97% of the epoxy molding compound of the molding part 140 is solidified when the epoxy molding compound is separated from the mold after completion of the molding process, and thus it is almost in a solid state. Then, a film capable of shielding an electromagnetic wave is attached onto the outer surface of the molding part 140 (which is cured to have about 97% solidified), and then high temperature heat is applied to the molding part 140 and the film, thereby curing completely the molding part and the film.

When forming the electromagnetic shielding part 150 with a coatable or paintable material containing electrically conductive particles, the material containing the electrically conductive particles is evenly sprayed to the outer surface of the molding part 140 and the sprayed material is cured with high temperature heat, thereby forming the electromagnetic shielding part 150 over the outer surface of the molding part 140. It may be possible to proceed the process of curing the sprayed material containing the electrically conductive particles together with the process of curing the molding part 140.

As such, when the electromagnetic shielding part 150 is formed using a film or a paintable material, there are advantages that the fabrication process can be made simple and the fabrication time required for forming the electromagnetic shielding part 150 can be shortened when compared to the case of forming the electromagnetic shielding part 150 using the molding resin.

As is apparent from the above description, in an embodiment of the present invention, the electromagnetic shielding part 150 is formed over the outer surface of the molding part 140 in forming the electromagnetic shielding part of the material containing the electrically conductive particle and thus an electromagnetic wave can be shielded perfectly through the large amount of the electrically conductive particle, thereby improving a reliability of a product.

In addition, the possibility of the conductive wires short circuited due to the conductive nature of the electromagnetic shielding part 150 is not existent, because the large amount of the electrically conductive particles is formed over the outer surface of the molding part 140. This not only improves the mechanical strength but also the manufacturing yield of the semiconductor package 100.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package, comprising:
a semiconductor chip; and
an encapsulant for covering the semiconductor chip,
wherein the encapsulant comprises:
a molding part for covering the semiconductor chip to protect the semiconductor chip from the external environment; and
an electromagnetic shielding part for covering the outer surface of the molding part and containing therein electrically conductive particles for blocking electromagnetic wave radiating outwardly from the semiconductor chip and shielding the semiconductor chip from external electromagnetic waves.

2. The semiconductor package according to claim 1, wherein the molding part is formed of an epoxy molding compound.

3. The semiconductor package according to claim 1, wherein the electromagnetic shielding part is formed of an epoxy molding compound containing electrically conductive particles.

4. The semiconductor package according to claim 1, wherein the electromagnetic shielding part is formed of a film containing electrically conductive particles.

5. The semiconductor package according to claim 1, wherein the electromagnetic shielding part is formed of paints containing electrically conductive particles.

6. The semiconductor package according to claim 1, electrically conductive particle is any one selected from group consisting of carbon, metal, and ferrite.

7. The semiconductor package according to claim 1, wherein the electrically conductive particles are in an amount of 1 to 50% of the weight of the electromagnetic shielding part.

8. A semiconductor package, comprising:
a base substrate having electrode terminals;
a semiconductor chip attached onto an upper surface of the base substrate, the semiconductor chip having a plurality of bonding pads over the upper surface of the semiconductor chip;
conductive wires electrically connecting each bonding pad of the semiconductor chip to a predetermined one of the electrode terminals of the base substrate;
a molding part for covering the upper surface of the base substrate including the semiconductor chip and the conductive wires;
an electromagnetic shielding part for covering the outer surface of the molding part and containing therein electrically conductive particles for blocking electromagnetic wave radiating outwardly from the semiconductor chip and shielding the semiconductor chip from external electromagnetic waves; and
an external connection terminal attached to a lower surface of the base substrate.

9. The semiconductor package according to claim 7, wherein the molding part is formed of an epoxy molding compound.

10. The semiconductor package according to claim 7, wherein the electromagnetic shielding part is formed of an epoxy molding compound containing electrically conductive particles.

11. The semiconductor package according to claim 7, wherein the electromagnetic shielding part is formed of a film containing electrically conductive particles.

12. The semiconductor package according to claim 7, wherein the electromagnetic shielding part is formed of paints containing electrically conductive particles.

13. The semiconductor package according to claim 7, electrically conductive particle is any one selected from group consisting of carbon, metal, and ferrite.

14. The semiconductor package according to claim 7, wherein the electrically conductive particles are in an amount of 1 to 50% of the weight of the electromagnetic shielding part.
